(19) United States
(12) Patent Application Publication
(10) Pub. No.: US 2026/0016652 A1
(43) Pub. Date: Jan. 15, 2026

(54) SLIDING TRAY ENCLOSURE AND FIBER OPTIC ORGANIZING SYSTEM

(71) Applicant: AFL Telecommunications LLC, Duncan, SC (US)

(72) Inventors: Aran James Russell Davidson, Chesham (GB); Mark Vogel, Chesham (GB)

(21) Appl. No.: 18/992,062

(22) PCT Filed: Jul. 7, 2023
(86) PCT No.: PCT/US2023/027091

§ 371 Date: Jan. 7, 2025

Related U.S. Application Data
(60) Provisional application No. 63/359,553, filed on Jul. 8, 2022.

(51) Int. Cl. G02B 6/44; H05K 7/18

(52) U.S. Cl. CPC G02B 6/44526; G02B 6/44528; G02B 6/44785; H05K 7/183; H05K 7/186

(57) ABSTRACT

A fiber optic tray enclosure is provided, including a base tray including a base wall extending along a lengthwise direction and a widthwise direction. the base wall forming a fastener opening configured to receive a fastener. The side wall is attachable to the base wall at the fastener opening. A plurality of mount plates is attachable to the base wall and separated from one another along the lengthwise direction. The mount plates forming an opening configured to receive a telecommunications adapter. A top wall is attachable to the mount plate, wherein the top wall, the base wall, the side wall, and the pair of mount plates form an interior volume therebetween.

### CROSS-REFERENCE TO RELATED APPLICATION

The present application is related and has right of priority to U.S. Provisional Patent Application No. 63/359,553 entitled “Sliding Tray Enclosure” filed on Jul. 8, 2022, the entirety of which is incorporated by reference for all purposes.

### FIELD

The present disclosure relates generally to telecommunications racks and closures, and more particularly to improved tray designs for high-density. hyperscale applications.

### BACKGROUND

Existing fiber optic network technology is based upon cassette systems using a sliding shelf to secure cassettes for an application that could utilize a complete shelf, rather than inefficient use of multiple cassettes on a shelf. Cassettes are often unique to the application, such as the tray, shelf, or rack onto which the cassette is placed. For example, cassettes may be configured as Base-8, Base-12, or Base-16, may include splicing or pre-terminated or pass-through cables, or combinations thereof.

Accordingly, improved trays for high-density fiber optic telecommunications applications which address one or more of the above-recognized issues would be advantageous and desired in the art.

### BRIEF DESCRIPTION OF THE INVENTION

Aspects and advantages of the invention will be set forth in part in the following description, or may be obvious from the description, or may be learned through practice of the invention.

An aspect of the present disclosure is directed to a fiber optic tray enclosure. The fiber optic tray enclosure includes a base tray including a base wall extending along a lengthwise direction and a widthwise direction, the base wall forming a fastener opening configured to receive a fastener. A side wall is attachable to the base wall at the fastener opening. A plurality of mount plates is attachable to the base wall and separated from one another along the lengthwise direction, the mount plates forming an opening configured to receive a telecommunications adapter. A top wall is attachable to the mount plate. The top wall, the base wall, the side wall, and the pair of mount plates form an interior volume therebetween.

Another aspect of the present disclosure is directed to a fiber optic organizing system. The fiber optic organizing system includes a shelf including a rail extending along a lengthwise direction. A tray enclosure includes a base tray having a base wall extending along the lengthwise direction and a widthwise direction. The base wall forms a fastener opening configured to receive a fastener, the base tray forming a tray runner guide positioned at a distal end along the widthwise direction. The tray enclosure is attachable to the shelf at the rail via the tray runner guide. A side wall is attachable to the base wall at the fastener opening. A plurality of mount plates is attachable to the base wall and separated from one another along the lengthwise direction, the mount plates forming an opening configured to receive a telecommunications adapter. A top wall is attachable to the mount plate. The top wall, the base wall, the side wall, and the pair of mount plates form an interior volume therebetween.

These and other features, aspects and advantages of the present invention will become better understood with reference to the following description and appended claims. The accompanying drawings, which are incorporated in and constitute a part of this specification, illustrate embodiments of the invention and, together with the description, serve to explain the principles of the invention.

### BRIEF DESCRIPTION OF THE DRAWINGS

A full and enabling disclosure of the present invention, including the best mode thereof, directed to one of ordinary skill in the art, is set forth in the specification, which makes reference to the appended figures.

FIG. 1 is a perspective view of an embodiment of a tray enclosure in an exemplary embodiment of a portion of a fiber optic shelf in accordance with aspects of the present subject matter.

FIG. 2 is a detailed perspective view of an embodiment of a portion of the tray enclosure and fiber optic shelf of FIG. 1 in accordance with aspects of the present subject matter.

FIG. 3 is a perspective view of an embodiment of the tray enclosure in accordance with aspects of the present subject matter.

FIG. 4 is a partially exploded perspective view of an embodiment of the tray enclosure in accordance with aspects of the present subject matter.

FIG. 5 is a partially exploded perspective view of an embodiment of a portion of the tray enclosure in accordance with aspects of the present subject matter.

FIG. 6 is a top-down view of an embodiment of the tray enclosure in accordance with aspects of the present subject matter.

FIG. 7 is a perspective view of an embodiment of a portion of an embodiment of the tray enclosure in accordance with aspects of the present subject matter.

FIG. 8 is a perspective view of an embodiment of a portion of an embodiment of the tray enclosure in accordance with aspects of the present subject matter.

### DESCRIPTION OF THE INVENTION

Reference now will be made in detail to embodiments of the invention, one or more examples of which are illustrated in the drawings. Each example is provided by way of explanation of the invention, not limitation of the invention. In fact, it will be apparent to those skilled in the art that various modifications and variations can be made in the present invention without departing from the scope or spirit of the invention. For instance, features illustrated or described as part of one embodiment can be used with another embodiment to yield a still further embodiment. Thus, it is intended that the present invention covers such modifications and variations as come within the scope of the appended claims and their equivalents.

The present disclosure is directed to a single multifunction tray or shelf allowing for selectively interchangeable disposition of fiber optic components, allowing pre-term, pass-through, splicing, and Base-8, Base-12, Base-16 and Base-24, through the use of interlocking bosses, components, dividing walls, and covers.

Interlocking components and dividing walls may allow for a greater range of fiber optic applications in a single unit. Embodiments provided herein may optimize a volume available for optical fibers, such as due to an absence of features to manage insertion and retention of cassettes/modules. Embodiments of the sliding tray provided herein may be inserted or removed from either the front or rear of a shelf or rack.

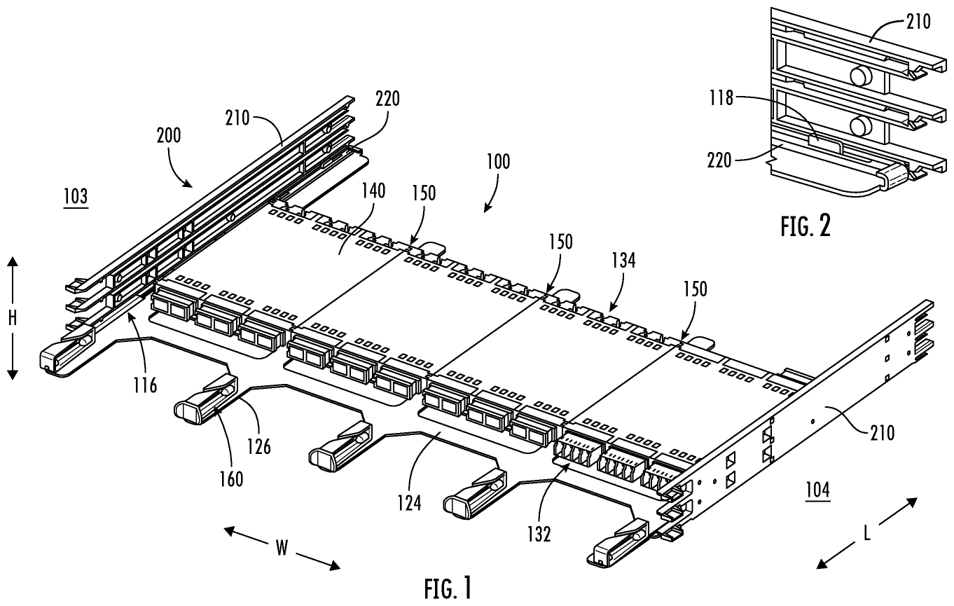

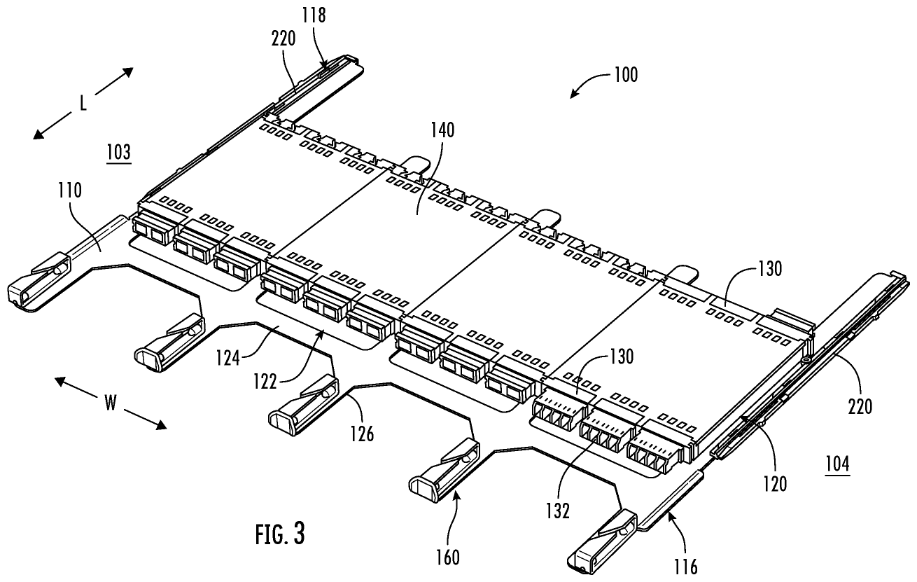

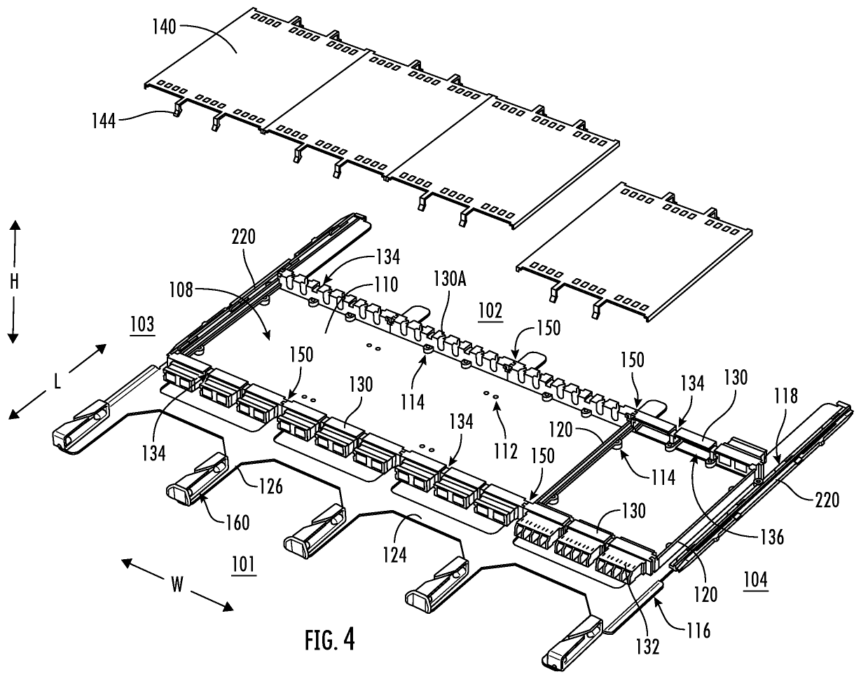

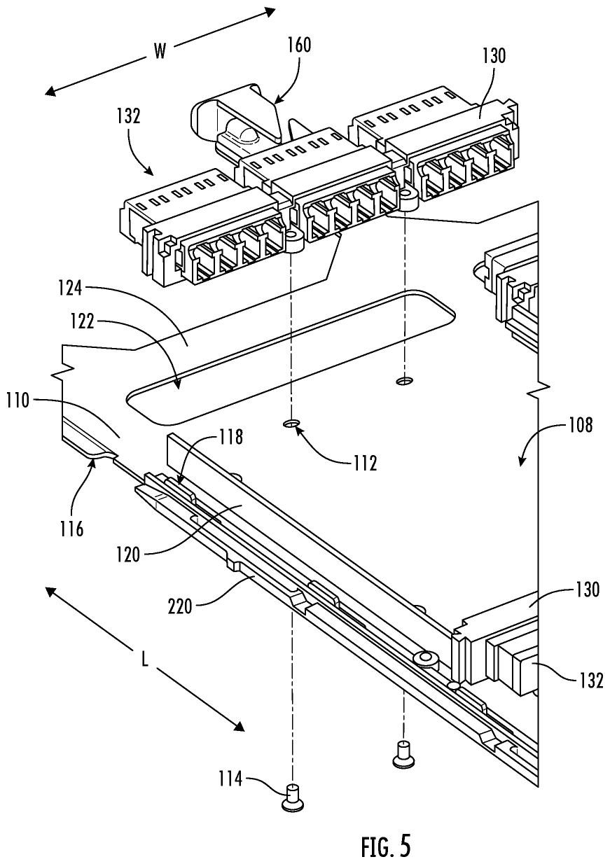

Referring now to the drawings, FIGS. 1-8 provide views of a tray enclosure 100 and accessories therefor. FIG. 1 depicts an embodiment of a fiber optic organizing system including the tray enclosure 100 mounted via rails 210 onto a shelf 200, such as a datarack, cabinet, or shelf for a fiber optic system. The tray enclosure 100 includes a base tray 110. The base tray 110 forms a base wall 108 extending along an area extending along a widthwise direction W and a lengthwise direction L. Fastener openings 112 (FIG. 4-5) are formed through the base wall 108. A fastener 114 (FIG. 5) is receivable through the opening 112 to attach various components to the base tray 110. In various embodiments, the fastener 114 is a screw, bolt, tie rod, or other threaded member, or rivet, pin, washer, nut, or other mechanical fastener. In an exemplary embodiment, the fastener 114 is a self-tapping screw, such as a countersunk self-tapping screw, allowing for insertion into, and retention at, the opening 112, and selective removal therefrom. However, it should be appreciated that any appropriate type of fastener may be utilized.

Tray enclosure 100 may include a side wall 120 attachable to the base tray 110, such as at opening 112 via fastener 114. Side wall 120 may extend along the lengthwise direction L and positioned at various stations along the widthwise direction W. Side wall 120 may form end walls at distal ends 103, 104 of the base tray 110 along the widthwise direction W. Side wall 120 may be positioned along the widthwise direction W between distal ends 103, 104 of the base tray 110 to form separate areas or volumes along the base tray 110.

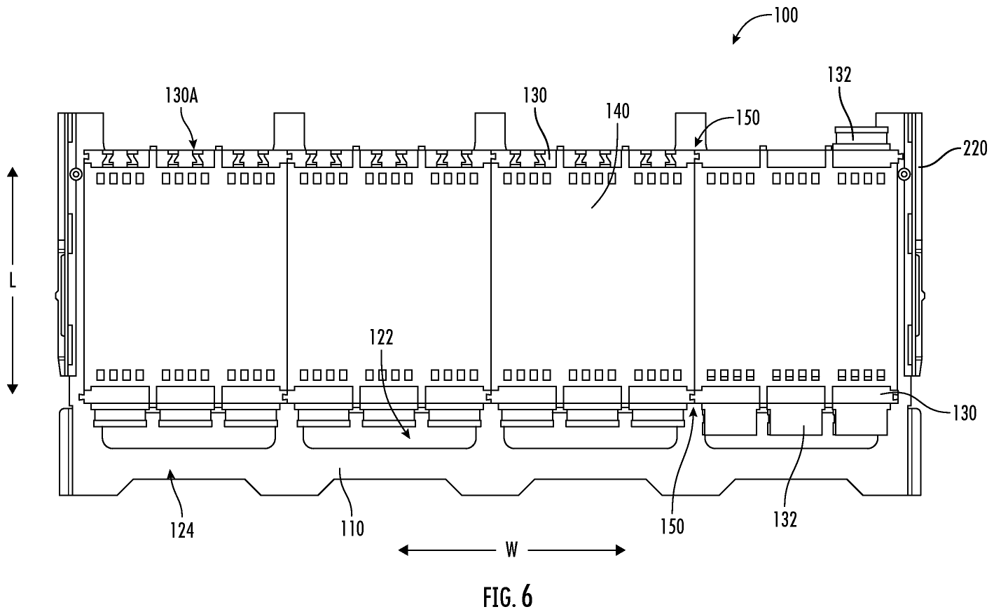

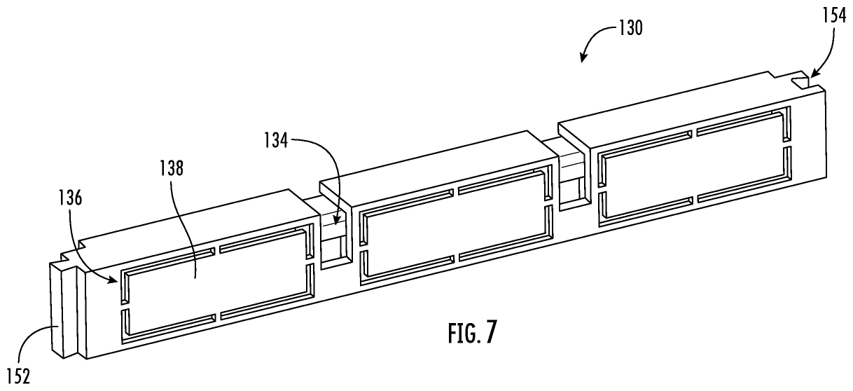

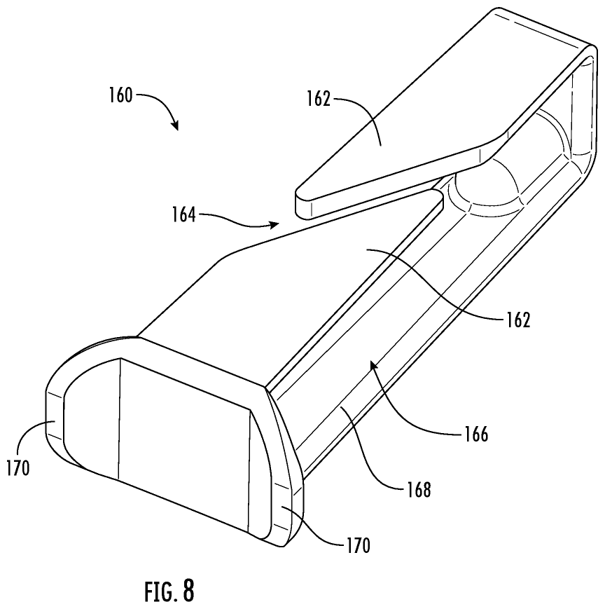

Tray enclosure 100 includes a mount plate 130. The mount plate 130 is attachable to the base tray 110 at opening 112, such as depicted in FIG. 5. The mount plate 130 is configured to receive and attach a telecommunications adapter 132, such as depicted in FIG. 7. The telecommunications adapter 132 may include any appropriate telecommunications or fiber optic adapter, such as, but not limited to, an LC, SC, MPO, etc. connector). In still various embodiments, the mount plate 130 may form a patch cord, preterm manager, or other routing, pass-through, or mount apparatus for telecommunications cables or adapters, such as depicted in FIG. 4 and FIG. 6 at mount plate 130A.

Referring to FIG. 7, a perspective view of an embodiment of the mount plate 130 is provided. The mount plate 130 includes an opening 136 configured to selectively receive the adapter 132 (FIGS. 1-5) therethrough. The mount plate 130 may include a removeable cover plate 138, such as to obscure or cover the opening 136 and inhibit entry into an interior of the tray enclosure 100. Referring to FIG. 4, the mount plate 130 is attached onto the base wall 108 at a forward end 101 and a rear end 102 along the lengthwise direction L. For instance, a plurality of mount plates 130 may be attached to the base wall 108 and positioned in adjacent arrangement along the widthwise direction L.

The tray enclosure 100 includes a removable top wall 140, such as depicted in FIG. 4. The top wall 140 is configured to provide a top cover opposite of the base wall 108. The top wall 140 is attachable to the mount plate 130. Referring to FIG. 4 and FIG. 7, the mount plate 130 includes a latch opening 134 configured to receive a latch member 144 extending from the top wall 140. Accordingly, the top wall 140 extends substantially along the widthwise direction W and the lengthwise direction L when positioned onto mount plate 130. Furthermore, an interior volume at which optical fibers, fiber optic components, splices, etc. is formed between the base wall 108 separated along a height H from the top wall 140, and between a pair of sidewalls 120 separated along the widthwise direction W and at least a pair of mount plates 130 separated along the lengthwise direction L.

In various embodiments, a plurality of mount plates 130 are attachable to one another at an interlocking interface 150. Referring to FIG. 7, the interlocking interface 150 includes a first end lock interface 152 and a second end lock interface 154. For instance, the first end lock interface 152 at the mount plate 130 may form a male interface insertable into the second end lock interface 154 forming a female interface at an adjacent mount plate 130. Each mount plate 130 may include the lock interfaces 152, 154 separated from one another along the widthwise direction W, such as to allow pairs of mount plates 130 to attach to one another to form the interlocking interface 150. The interlocking interface 150 may advantageously improve stiffness across the tray enclosure 100. The improved stiffness may facilitate mounting components generally associated with a fiber optic cassette directly onto the base tray. For instance, the interlocking interface 150 may mitigate bending, warping, or displacement of components at the base tray, such as may be associated with weight and dimension of an assembly including fiber optic cassette components directly onto a tray without requiring a cassette or other enclosure.

Referring to FIGS. 1-5, in various embodiments, the base tray 110 includes a tray runner guide 116 positioned at one or both distal ends 103, 104 along the widthwise direction W. Embodiments of the base tray 110 include the tray runner guide 116 extending along the lengthwise direction L. The tray runner guide 116 may generally form a tab protruding from the base wall 108 along the widthwise direction W, and extending along the lengthwise direction L (e.g., for a greater distance than the protrusion along the widthwise direction W). The tray runner guide 116 is configured to direct or orient the rail 210 onto the base tray 110. The tray runner guide 116 may further, or alternatively, direct or orient a shelf guide 220 onto the base wall 108.

In still various embodiments, the base tray 110 includes a tray runner tab 118 positioned at one or both distal ends 103, 104 along the widthwise direction W. Embodiments of the base tray 110 include the tray runner tab 118 extending along the lengthwise direction L. The tray runner tab 118 may generally form a protrusion extending from the base wall 108 along the height H, and extending along the lengthwise direction L (e.g., for a greater distance than the protrusion along the height H). One or more tray runner tabs 118 may be positioned at one or both distal ends 103, 104.

The tray runner tab 118 is configured to receive the shelf guide 220. The shelf guide 220 is selectively attachable to the base wall 108 and the tray runner tab 118 provides a locating feature to set a position of the shelf guide 220 relative to the base wall 108. The shelf guide 220 may generally form a rail, bracket, or adapter configured to provide an attachment interface between the base tray 110 and the rail 210 at the shelf 200.

Embodiments of the tray enclosure 100 may provide a housing and attachment apparatus for fiber optic components, such as adapters, connectors, splices. splitters, expanders, cables, etc., at and within a unit including a unitary, monolithic base tray 110 and a plurality of selectively attachable mount plates 130, top walls 140, and side walls 120. Various embodiments of the tray enclosure 100 may include the shelf guide 220, or the shelf guide 220 may be included or integrated to the shelf 200 or rail 210. Accordingly, a single base wall 108 may support a plurality of mount plates 130, top walls 140, and side walls 120, and fiber optic components within an interior volume or attached to the base tray 110, as a single unit. Such single units allow for customization, including on-site customization, of fiber optic components.

Various embodiments of the tray enclosure 100 may include the base tray 110 forming a handle opening 122 between the base wall 108 and a handle 124. For instance, the handle 124 may extend along the widthwise direction W. The handle opening 122 allows for a user's hands (e.g., fingers) to extend into the opening 122 and push or pull the tray enclosure 100 along the lengthwise direction L.

In still various embodiments, a member 126, such as a tab, extends along the lengthwise direction L from the handle 124. An organizer device 160 may be selectively positioned at the member 126. The organizer device 160 may form a patchcord or preterm manager, cable manager, or other device for organizing routing of fiber optic components. Referring to FIG. 8, the organizer device 160 may include a tab 162, or a pair of opposing tabs 162 forming a slit or opening 164 therebetween, such as to allow cables, leads, etc., to attach or rest onto the organizer device 160. The organizer device 160 may form an area 166 between the tab(s) 162 and a member 168.

Various embodiments of the organizer device 160 may include a tab 170 extending outward from the member 168, such as to form a handle or pull tab at which a user may articulate the base tray 110. The tab 170 may protrude along the lengthwise direction L, along the widthwise direction W, or both, such as toward a forward or rear end at which the user may be positioned relative to the tray enclosure 100.

Embodiments depicted and described herein provide a fiber optic tray enclosure and organizing system allowing for configuring a cassette as a fanout, a splitter module, a pass-through, or other desired configuration, allowing for eliminating a need to inventory various cassettes and eliminating long lead-times associated with build-to-order apparatuses. Embodiments provided herein may allow for various adapter types to be received at a single tray configuration (e.g., LC, SC, MPO, etc.). For instance, embodiments provided herein may allow for a single configuration to provide a combination, or all, of cassette configurations such as provided herein.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they include structural elements that do not differ from the literal language of the claims, or if they include equivalent structural elements with insubstantial differences from the literal languages of the claims.

What is claimed is:

1. A fiber optic tray enclosure, comprising:
a base tray comprising a base wall extending along a lengthwise direction and a widthwise direction, the base wall forming a fastener opening configured to receive a fastener;
a side wall attachable to the base wall at the fastener opening;
a plurality of mount plates attachable to the base wall and separated from one another along the lengthwise direction, the mount plates forming an opening configured to receive a telecommunications adapter; and
a top wall attachable to the mount plate, wherein the top wall, the base wall, the side wall, and the pair of mount plates form an interior volume therebetween.

2. The fiber optic tray enclosure of claim 1, the mount plate comprising a latch opening configured to receive a latch at the top wall.

3. The fiber optic tray enclosure of claim 1, wherein the plurality of mount plates are attachable to one another at an interlocking interface.

4. The fiber optic tray enclosure of claim 3, the interlocking interface comprising a first end lock interface insertable into a second end lock interface.

5. The fiber optic tray enclosure of claim 3, wherein a pair or more of the plurality of mount plates each comprise the first end lock interface separated from a second end lock interface along the widthwise direction.

6. The fiber optic tray enclosure of claim 5, wherein the first end lock interface forms a male interface insertable into the second end lock interface forming a female interface at an adjacent mount plate.

7. The fiber optic tray enclosure of claim 1, the base tray comprising a tray runner guide positioned at a distal end along the widthwise direction.

8. The fiber optic tray enclosure of claim 7, the tray runner guide extending along the lengthwise direction and protruding from the base wall along the widthwise direction.

9. The fiber optic tray enclosure of claim 1, the base tray comprising a tray runner tab positioned at a distal end along the widthwise direction, the tray runner tab extending along the lengthwise direction and protruding from the base wall along a height.

10. The fiber optic tray enclosure of claim 1, wherein the base tray comprises a single base wall configured to receive the plurality of mount plates and the side wall at respective fasteners at the single base wall.

11. The fiber optic tray enclosure of claim 1, the base tray forming a handle opening between the base wall and a handle.

12. The fiber optic tray enclosure of claim 1, the base tray comprising an organizer device positioned at a member extending from the base wall, the organizer device configured to receive a fiber optic cable.

13. The fiber optic tray enclosure of claim 12, the organizer device comprising a tab extending outward from a member at the organizer device, the tab protruding along the lengthwise direction, the widthwise direction, or both.

14. A fiber optic organizing system. comprising:
a shelf comprising a rail extending along a lengthwise direction;
a tray enclosure comprising;
a base tray comprising a base wall extending along the lengthwise direction and a widthwise direction, the base wall forming a fastener opening configured to receive a fastener, the base tray forming a tray runner guide positioned at a distal end along the widthwise direction, the tray enclosure attachable to the shelf at the rail via the tray runner guide;
a side wall attachable to the base wall at the fastener opening;
a plurality of mount plates attachable to the base wall and separated from one another along the lengthwise direction, the mount plates forming an opening configured to receive a telecommunications adapter; and
a top wall attachable to the mount plate, wherein the top wall, the base wall, the side wall, and the pair of mount plates form an interior volume therebetween.

15. The fiber optic organizing system of claim 14, the mount plate comprising a latch opening configured to receive a latch at the top wall.

16. The fiber optic organizing system of claim 14, wherein the plurality of mount plates are attachable to one another at an interlocking interface.

17. The fiber optic organizing system of claim 16, the interlocking interface comprising a first end lock interface insertable into a second end lock interface.

18. The fiber optic organizing system of claim 16, wherein a pair or more of the plurality of mount plates each comprise the first end lock interface separated from a second end lock interface along the widthwise direction.

19. The fiber optic organizing system of claim 18, wherein the first end lock interface forms a male interface insertable into the second end lock interface forming a female interface at an adjacent mount plate.

20. The fiber optic organizing system of claim 14, wherein the base tray comprises a single base wall configured to receive the plurality of mount plates and the side wall at respective fasteners at the single base wall.
